(19) United States
(12) Patent Application Publication
(10) Pub. No.: US 2008/0136678 A1
(43) Pub. Date: Jun. 12, 2008

(54) DATA INPUT USING KNOCKS

(75) Inventor: Nathan John Harrington, Cary, NC (US)

Correspondence Address: IBM CORPORATION, IPLAW SHCB/40-3, 1701 NORTH STREET, ENDICOTT, NY, 13760, US

(73) Assignee: INTERNATIONAL BUSINESS MACHINES CORPORATION, Armonk, NY (US)

(21) Appl. No.: 11/609,028

(22) Filed: Dec. 11, 2006

(51) Int. Cl. H03M 11/00

(52) U.S. Cl. 341/20

(57) ABSTRACT

Data is entered into an electronic device using a unique pattern of knock sequences applied to the surface of the device. One or more accelerometers within the device provide an electronic output which is sampled and digitized. Matching software compares the sequences to previously recorded sequences for user identification. The user may also use a prespecified code for entering knock data.

### FIELD OF THE INVENTION

The invention relates to methods, systems, and program products for entering data into an electronic device using knocks on the device, and particularly using specific sequences of knocks to denote specific data elements. Even more particularly, the invention relates to use of accelerometers or the like in combination with matching software for detecting and decoding specific sequences of knocks onto the case of laptops, PDA's, cell phones, and other portable or fixed electronic devices.

### BACKGROUND OF THE INVENTION

Current manual data entry methods for electronic devices include keyboards, mice, and touch screens, all of which are well known. Various modifications and inventive improvements have been made to these devices for specific purposes, usually related to differing data entry needs, e.g., wireless keyboards and mice, specialized key layouts, touch screens with stylus handwriting entry capability, etc.

Recently, Linjama in U.S. Patent Application US 2004/0169674 describes the use of a motion sensor in a portable electronic device, to detect a gesture by a user. The gesture involves touching or tapping on the surface of the device. The motion sensor detects the gesture (which may be multiple taps), and the device provides a feedback, for example, vibrating pulses, to the user. The gesture may also be used to select or activate a function of the device, including scrolling a list or moving a game cursor.

Haggman et al., in U.S. Patent Application U.S. 2006/0097983 describe using one or more motion sensors to detect a tap and determine the location of the tap upon the surface of the device. For example, the tap may be determined to be in a predefined location upon an attached tapping template, such as an image of a keyboard. The user can therefore enter keyboard types of data into a device lacking a full keyboard, such as a cellular phone. The device may also use the location information in combination with a count of the number of taps or the orientation of the device to distinguish various entries.

The Linjama and Haggman applications shall be incorporated herein by reference in their entireties for any purpose.

There continues to exist further needs for manual data entry methods for electronic devices, particularly portable devices which may have limited data entry capability. Specific applications may also lend themselves to new and unique manual data entry methods due to the nature of the application.

Automated data entry methods, such as speech recognition, document scanning, and file transfers from memory key devices are all currently used. However, the present invention is directed to improvements in manual data entry methods.

### OBJECTS AND SUMMARY OF THE INVENTION

It is therefore a principal object of the present invention to enhance the manual data entry art by providing a method with unique data entry capabilities.

It is another object to provide such a method wherein enhanced operational capabilities are possible.

It is a further object to provide such a method which can be utilized in a relatively inexpensive manner.

These and other objects are attained in accordance with one embodiment of the invention wherein there is provided a method of identifying a user, comprising the steps of; tapping by a known user having a user identification, a sequence of knocks having a plurality of spacings or a plurality of strengths, onto an electronic device having an accelerometer contained therein, the accelerometer having an electronic output, sampling and digitizing the electronic output, and storing the digitized output in association with the user identification, thereafter, receiving a second sequence of knocks on the electronic device resulting in a second electronic output, sampling and digitizing the second electronic output, matching the digitized second electronic output to the stored digitized output, and if a match exists, providing the user identification

In accordance with another embodiment of the invention, there is provided a method of entering data into an electronic device, comprising the steps of, tapping a sequence of knocks having a plurality of spacings or a plurality of strengths, using a preselected code, onto an electronic device having an accelerometer contained therein, the accelerometer having electronic output, sampling and digitizing the electronic output, and analyzing the digitized output using software and the preselected code to convert the digitized output to a sequence of data characters.

### BRIEF DESCRIPTION OF THE DRAWINGS

FIG. 1 is a flowchart of steps for verifying a user in accordance with the present invention;

FIG. 2 illustrates tapping the side of a laptop display; and

FIG. 3 is a flowchart of steps for entering data using a prespecified code.

### BEST MODE FOR CARRYING OUT THE INVENTION

As noted above, the present invention provides alternative methods for entering data into an electronic device based upon unique sequences of knocks. Depending on the intended use, such methods may provide advantages over other known ways of entering data.

For a better understanding of the present invention, together with other and further objects, advantages, and capabilities thereof, reference is made to the following disclosure and the appended claims in connection with the above-described drawings.

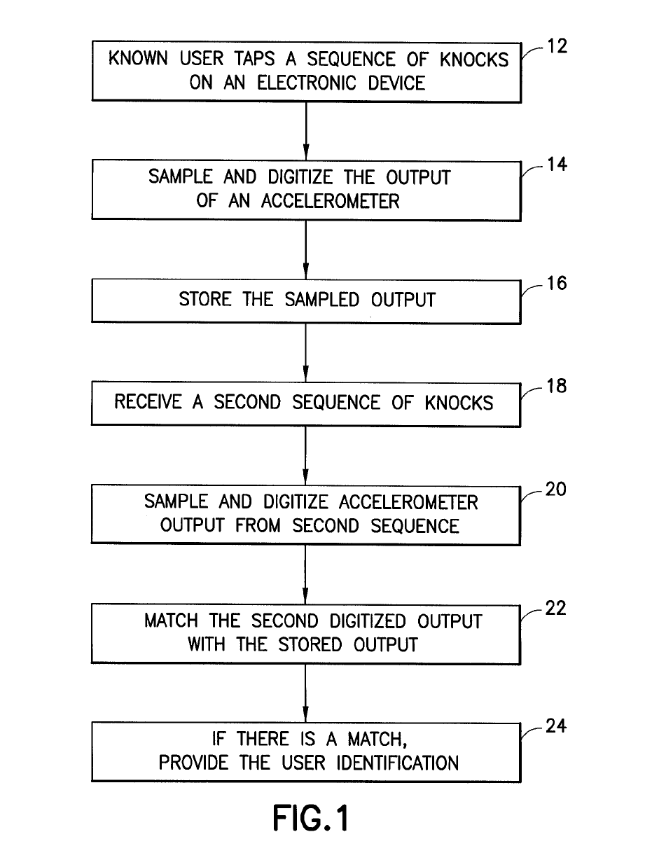

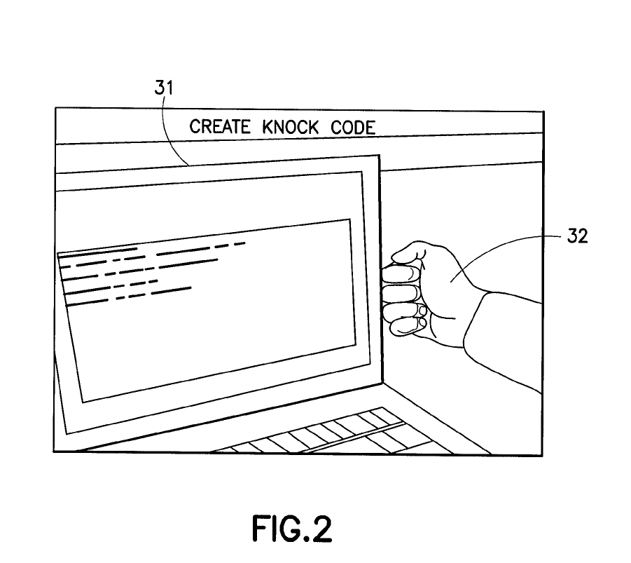

In FIG. 1, there is shown a flowchart of steps performed in accordance with one embodiment of the present invention. The application is to verify, e.g., for security purposes, a user of the electronic device by receiving a secret knock sequence as a type of password. In step 12, a known user taps a unique sequence of knocks onto an electronic device. An illustration of a user 32 tapping on an electronic device 31 is shown in FIG. 2 which is described below. The user is entering a new password as a unique sequence of knocks. Various sequencing methods may be used, such as sequences having a unique pattern of times between knocks, or knocks of differing strengths. For example, the knocks may be spaced to represent the spacing between notes of a tune, or words of a poem, such as “Mary had a Little Lamb” or “shave and a haircut, two bits.” Another example may be a sequence of soft-hard-soft-soft strengths or short-long-short-short timings or quick-slow-quick-quick as used in ballroom dance instruction. This example demonstrates the letter “L” in the International Morse code signaling system. Reference is made to U.S. Pat. No. 1,647 by S. F. B. Morse and to International Telegraphic Union ITU-R Recommended standard M.1677 (2004) for additional details on known Morse code signaling methods. The Morse patent and ITU-R standard shall be incorporated herein by reference in their entireties for any purpose.

For security reasons, the knock sequence should be long enough to deter easy guessing by malicious persons attempting to intrude on the user's resources, but short enough to be readily committed to memory by the user. Moreover, a simple knock counting system, such as one knock for user A, two knocks for user B, etc., would obviously be unacceptable from a security standpoint, although such systems are acceptable for command differentiation as describe by Linjama and Haggman.

While the example sequences given above use a binary system of spaces, or a binary level of strengths, it would be obvious to those of ordinary skill in the signaling arts that more than two levels of spacing or strength may be used if such additional complexity is warranted or desired. Morse code is principally binary, having dot (short) and dash (long) elements.

The electronic device of step 12 may be any type of portable or fixed device, such as a laptop computer, personal digital assistant (PDA), cell phone, desktop computer, video DVD player, television set top box or any other electronic device attached to one of these, such as a display, a mouse, a keypad, a hard drive, diskette drive, video camera, or the like.

The electronic device of step 12 includes at least one accelerometer having an output signal. The accelerometer may perform other functions, such as detecting when a hard drive is subjected to mechanical shocks (including dropping the electronic device itself onto a hard surface). Any type of accelerometer known in the art or developed in the future may be used in step 12.

In step 14, the output of the accelerometer is sampled and digitized using known methods of sampling and conversion to digital form. The sampling must be performed sufficiently often to not miss a knock and to distinguish between different strength knocks or different spacings between knocks, e.g., at least 2-10 times faster than the minimum spacing between knocks. Digitization may record the amplitude of the acceleration at a sampling point in time. Alternatively digitization may record the time between knocks. Other known digitization methods may be used without departing from the spirit of the present invention.

In step 16, the sampled and digitized output is stored by the electronic device in association with the known user's identification, such as his/her name or logon id.

Subsequently, in step 18, the electronic device receives a sequence of knocks from the same or another user, providing a second electronic output from the one or more accelerometers. This second output is sampled and digitized in step 20 using the same techniques utilized in step 14.

In step 22, the second digitized output is matched to the stored digitized output. Matching may be performed using various matching techniques, including use of configurable threshold parameters. Threshold parameters operate by ignoring acceleration values less than a specified threshold. Background noise due to minor causes, such as insignificant earth tremors, small bumps to a table on which the device is resting, vibration from a delivery cart passing nearby, road vibrations due to use in a moving vehicle, shakiness or nervous twitches in a hand supporting a portable electronic device, are all thus eliminated preventing confusion with purposeful knocks or taps. Multiple thresholds may also be similarly used to distinguish between hard knocks, soft knocks, and background noise. The terms knocks and taps shall be taken herein as synonymous even though in everyday use a knock is typically made with a knuckle and a tap with any body part, but particularly with a fingertip. Knocks and taps may also be made herein using a stylus, either end of an ordinary eraser pencil, a stick, or any other suitable object.

Other matching techniques include compressing many rapid acceleration readings greater than a threshold value, into one knock event, and recording the time duration between knock events as a knock pattern. A subroutine then performs a simple difference check between the timing of the knocks for the second sequence of knocks and the stored sequence. With this technique, the minor differences between knocks is not compounded. Missing the timing on several knocks by a small amount will not accumulate into a total match failure.

It is often useful to initially compare the number of knocks, because with many matching techniques there is no point in comparing sequences with a differing number of knocks.

The total allowable match difference can also be checked against a threshold value to allow a certain level of knock deviation without allowing an inordinate number of erroneously matched patterns. Other types of matching techniques, known in the art may be used.

If a match is detected, then in step 24, the user identification stored in step 16, in association with the stored sampled and digitized output, is provided. It may be provided to a logon security application or to any other software application as needed in order to make use of this embodiment of the present invention.

In FIG. 2, there is shown the right hand of a user 32 knocking with the knuckles on the lower-right side of a laptop display 31. As noted above, any portion of an electronic device surface may be used in the present invention. While Haggman describes methods of detecting the location on the surface where a tap is made, this capability is not needed for the present invention, which depends solely on the knock sequence for data entry. It will be obvious to those of ordinary skill in the art that various combinations of the present invention with Haggman's techniques are possible if an application so warrants it.

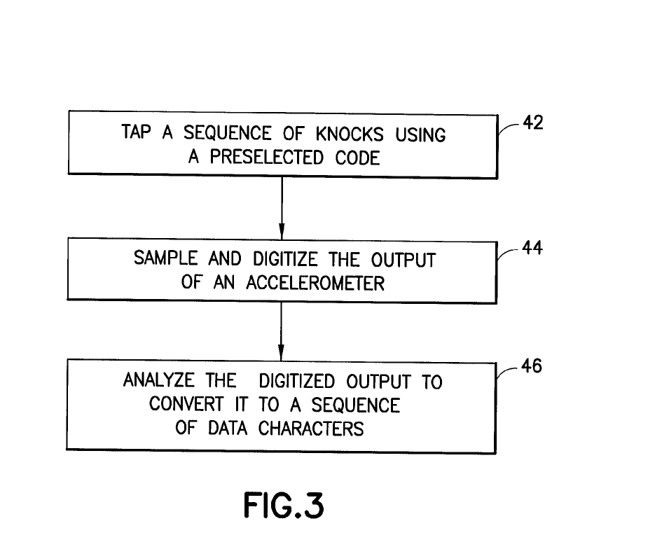

In FIG. 3, there is shown a flowchart of steps for entering data into an electronic device in accordance with another embodiment of the present invention. In step 42, a user taps a sequence of knocks, using a preselected code onto an electronic device. The sequence of knocks has a plurality of spacings or a plurality of strengths. For example, the preselected code may be the International Morse code as defined by ITU-R M.1677 standard, which is well known by many persons throughout the world. Any other code may also be used, including that described by S. F. B. Morse in his 1838 U.S. Pat. No. 1,647.

The electronic device has at least one accelerometer within it. Applicant notes that it is now common for manufacturers of laptop computers and other portable devices to include accelerometers whenever hard drives are included. The intended purpose of the accelerometers is to detect mechanical shocks and park or otherwise position the movable arm of the hard device to prevent damage to the sensitive recording surfaces from subsequent shocks. The accelerometer has an electronic output.

In step 44, the accelerometer output is sampled and digitized using techniques described above in connection with corresponding steps in FIG. 1.

In step 46, the digitized output is converted to a sequence of data characters. For example, if the preselected code in step 42 is International Morse Code, then the data characters may be ASCII characters representing are the letters, numbers, and punctuation symbols of the decoded Morse sequence (patterns of dots and dashes).

The techniques of matching described above may also be used in step 46, as appropriate. For example, threshold parameters, whether single or multiple, may be used to reduce or eliminate background noise. Other pattern matching techniques known in the art, including those having learning capabilities, e.g. for decoding Morse characters, may also be used.

While there have been shown and described what are at present considered the preferred embodiments of the invention, it will be obvious to those skilled in the art that various changes and modifications may be made therein without departing from the scope of the invention as defined by the appended claims.

What is claimed is:

1. A method of identifying a user, comprising the steps of:
tapping by a known user having a user identification, a sequence of knocks having a plurality of spacings or a plurality of strengths, onto an electronic device having an accelerometer contained therein, said accelerometer having an electronic output;
sampling and digitizing said electronic output, and storing the digitized output in association with said user identification;
thereafter, receiving a second sequence of knocks on said electronic device resulting in a second electronic output;
sampling and digitizing said second electronic output;
matching the digitized second electronic output to the stored digitized output; and
if a match exists, providing said user identification.

2. The method of claim 1, wherein said user identification is a logon id for an application or other computer software.

3. The method of claim 2, wherein said knocks are tapped at a prespecified location on said electronic device.

4. The method of claim 2, wherein said electronic device is a laptop, a PDA, or a cell phone.

5. The method of claim 1, wherein said electronic device has a plurality of accelerometers each having an electronic output.

6. The method of claim 5, wherein said plurality of accelerometers are used to identify shocks to a hard drive located in said electronic device.

7. The method of claim 1, wherein said matching is performed using total allowable match difference software.

8. A method of entering data into an electronic device, comprising the steps of:
tapping a sequence of knocks having a plurality of spacings or a plurality of strengths, using a preselected code, onto an electronic device having an accelerometer contained therein, said accelerometer having an electronic output;
sampling and digitizing said electronic output; and
analyzing the digitized output using software and said preselected code to convert said digitized output to a sequence of data characters.

9. The method of claim 8, wherein said knocks are tapped at a prespecified location on said electronic device.

10. The method of claim 8, wherein said electronic device is a laptop, a PDA, or a cell phone.

11. The method of claim 8, wherein said preselected code is international morse code or american morse code.

12. The method of claim 11, wherein a weak knock is used to denote a dot and a strong knock is used to denote a dash, or vice versa.

13. The method of claim 8, wherein said data characters are ASCII characters.

14. The method of claim 8, wherein said analyzing includes using configurable threshold parameters.

15. The method of claim 14, wherein one of said parameters is an acceleration level threshold used to minimize the effects of background noise.
